(19) United States
(12) Patent Application Publication
(10) Pub. No.: US 2012/0244684 A1
(43) Pub. Date: Sep. 27, 2012

(54) FILM-FORMING APPARATUS AND METHOD

(76) Inventors: Kunihiko Suzuki, Shizuoka (JP); Hideki Ito, Kanagawa (JP)

(21) Appl. No.: 13/404,117

(22) Filed: Feb. 24, 2012

(30) Foreign Application Priority Data
Mar. 24, 2011 (JP) 2011-066130
Nov. 18, 2011 (JP) 2011-253333

(51) Int. Cl. H01L 21/205; C23C 16/46; C23C 16/00

(52) U.S. Cl. 438/478; 118/724; 118/725; 257/E21.101

(57) ABSTRACT

A film-forming apparatus and method is provided that includes a reflector and insulator capable of suppressing the thermal degradation of components in close proximity to the heater in a film-forming apparatus. In a film-forming apparatus the reflector is used in combination with insulator. Specifically, in a film-forming apparatus a reflector is disposed below a heater with the insulator placed below the reflector. The insulator absorbs the radiant heat from the heater thus suppressing an excessive rise in temperature around the heater, it is therefore possible to prevent thermal degradation of components in close proximity of the heater. For example, when the temperature of a semiconductor substrate is 1650° C., the temperature of the quartz heater base maybe about 1000° C. This is lower than the softening point temperature of the quartz heater base, preventing deformation of the heater base.

### CROSS-REFERENCE TO THE RELATED APPLICATION

The entire disclosures of Japanese Patent Application No. 2011-066130 filed on Mar. 24, 2011, and Japanese Application No. 2011-253333 filed on Nov. 18, 2011 including specification, claims, drawings and summary, on which the Convention priority of the present application is based, are incorporated herein in their entirety.

### FIELD OF THE INVENTION

The present invention relates to an apparatus and a method for film deposition.

### BACKGROUND

A single wafer film-forming apparatus is often used to deposit a monocrystalline film such as a silicon film or the like, on a substrate or wafer, thereby forming an epitaxial wafer.

A film-forming apparatus is constructed so that a deposition gas will be supplied into a film-forming chamber in which a susceptor is located, a substrate is placed on the susceptor, and an epitaxial film will be formed on the surface of the substrate by heating the back surface of the wafer. In an apparatus using a back heating system there is no heating source in the upper part of the apparatus. The deposition gas is supplied to the susceptor from a vertical direction, and then the gas flows in a laminar direction across the surface of the wafer to create a uniform epitaxial film.

In addition, the film-forming apparatus has a support portion for the susceptor, a rotating shaft (for rotating the susceptor on a rotational axis) extending downwardly through the through-holes in the bottom wall portion of the film-forming chamber, a rotating mechanism for rotating the rotating shaft, placed in the lower section of the film forming chamber. By rotating the wafer during film-forming, a film of uniform thickness can be formed, see for example Japanese Laid-Open Patent HEI 5-152207.

A resistance heater is used as a heat source for use in a film-forming apparatus. The heater must not deform at high temperatures or be manufactured from a material that will emit pollutants. SiC (silicon carbide) is a common constituent material used for manufacturing of the heater.

In the epitaxial growth of Si (silicon) films, the temperature of the wafer is heated to around 1200° C. At that time, the temperature of the heater is higher than that of the wafer. Therefore, components constituting the heater can deform and emit pollutants by heating to this temperature. An example of heater to be used in such application includes a heater constructed of sintered SiC.

In recent years, attention has been given to SiC (silicon carbide) instead of Si, as a semiconductor material to be used in high-voltage power semiconductor devices. SiC is characterized in that its energy gap is two or three times larger, and its dielectric breakdown field is about one digit larger than that of a conventional semiconductor material such as Si (silicon) or GaAs (gallium arsenide).

SiC epitaxial film is formed by supplying H₂ (hydrogen) as a carrier gas, SiH₄ (monosilane) and C₃H₃ (propane) to a SiC wafer. Specifically, these gases are supplied into a film forming chamber and then the gases flow as a substantially laminar flow on the upper surface of the SiC wafer placed on the heated susceptor. After that, an epitaxial growth reaction occurs on the upper surface of the SiC wafer until the gases are exhausted. The temperature of this reaction is higher than that of an epitaxial growth reaction of Si film. Therefore the temperature of the heater is higher than that of the epitaxial growth for Si film, approximately 2000° C.

The film-forming apparatus used for the epitaxial reaction mentioned above comprises a chamber, a gas supply system for supplying a deposition gas into the chamber, and a heating system in the chamber. The heating system comprises a heater and an electrically conductive busbar for supporting the heater, the busbar is supported by a heater base. A wiring portion is connected with the busbar to supply electricity to the heater.

In the film-forming apparatus, when the heater is operating, the surrounding components, that is, the busbar, the heater base, and the wiring unit and electrodes are heated by radiant heat from the heater. Of these components, the heater base is composed of quartz, the wiring unit and the rod electrodes are constituted of a metal, such as molybdenum. The heat resistantance of these components is lower than that of the SiC as a material for the heater. Therefore, there is a fear that these parts will degrade as a result of heat radiation from the heater.

The present invention has been made to address the above issues. That is, an object of the present invention is to provide a film-forming apparatus and a film-forming method that can prevent damage of components close to the heater by heat from the heater.

Other challenges and advantages of the present invention are apparent from the following description.

### SUMMARY OF THE INVENTION

In one embodiment of the present invention, a film-forming apparatus capable of reducing an excessive rise in the temperature of the components surrounding the heater, the film-forming apparatus comprising: a film-forming chamber, a first heater located in the film-forming chamber, a first reflector located below the first heater, and a first insulator located below the first reflector.

In another aspect of this embodiment, a film-forming apparatus wherein the first insulator is made of carbon fiber.

In another aspect of this embodiment, a film-forming apparatus further comprising a cylindrically-shaped liner covering an inner wall of the film-forming chamber, and a second heater located above the first heater, between the inner wall of the film-forming chamber and the liner.

In another aspect of this embodiment, a film-forming apparatus wherein the second heater is formed from a plurality of heaters provided in a vertical direction, and wherein the apparatus is comprised of a control unit for independently controlling the heaters.

In another aspect of this embodiment, a film-forming apparatus, wherein a second reflector is provided between the inner wall of the film-forming chamber and the second heater.

In another aspect of this embodiment, a film-forming apparatus wherein a second insulator is provided between the inner wall of the film-forming chamber and the second reflector.

In another aspect of this embodiment, a film-forming apparatus wherein the second insulator is made of carbon fiber.

In another aspect of this embodiment, a film-forming apparatus further comprising: a susceptor, provided in the film-forming chamber to place the substrate thereon, a electrically-conductive first support unit for supporting the first heater, a second support unit for supporting the first support unit, a rotary drum for supporting the susceptor at an upper section thereof, and further housing the first heater, the first support unit and the second support unit, a rotary shaft, located at a lower section of the film-forming chamber, for rotating the rotary drum, an electrode, located inside the rotary shaft, for conducting electricity through the first support unit to the first heater, an electrically-conductive connector penetrated by the upper section of the electrode, for fixing the electrode and for supporting the first support unit and the second support unit, wherein the first reflector and the first insulator are provided inside the rotary drum and between the first heater and the second support unit.

In another aspect of this embodiment, a film-forming apparatus, wherein the second support unit is made of quartz, and both the electrode and the connector are made of metal.

In another aspect of this embodiment, a film-forming apparatus wherein the first insulator is made of carbon fiber.

In another aspect of this embodiment, a film-forming apparatus further comprising: a cylindrically-shaped liner covering an inner wall of the film-forming chamber, and a second heater located above the first heater between the inner wall of the film-forming chamber and the liner.

In another aspect of this embodiment, a film-forming apparatus wherein the second heater is formed by a plurality of heaters provided in a vertical direction, and further comprising a control unit for independently controlling the heaters.

In another aspect of this embodiment, a film-forming apparatus wherein a second reflector is provided between the inner wall of the film-forming chamber and the second heater.

In another aspect of this embodiment, a film-forming apparatus wherein a second insulator is provided between the inner wall of the film-forming chamber and the second reflector.

In another aspect of this embodiment, a film-forming apparatus, wherein the second insulator is made of carbon fiber.

In a second embodiment of this invention, a film-forming method capable of reducing an excessive rise in the temperature of the components surrounding the heater, the film-forming method comprising: placing the substrate on a susceptor located in a rotary drum in a film-forming chamber, heating the substrate while rotating the rotary drum by a rotary shaft provided at a lower section of the film-forming chamber, and feeding a deposition gas into the film-forming chamber, providing an electrode inside the rotary shaft, providing a first heater, an electrically-conductive first support unit for supporting the first heater, a second support unit for supporting the first support unit, and an electrically-conductive connector for supporting the first support unit and the second support unit and for conducting electricity between the electrode and the first support unit, inside the rotary drum, providing a first reflector below the first heater, providing a first insulator below a first reflector and above the second support unit, and conducting electricity from the electrode to the first heater to heat the substrate.

In another aspect of this embodiment, a film-forming method comprising: covering the inner wall of the chamber with a liner, and wherein heating the substrate via the first heater and a second heater located above the substrate and between the inner wall of the film-forming chamber and the liner.

In another aspect of this embodiment, a film-forming method comprising: forming the second heater from a plurality of small heaters provided in a vertical direction, and heating the substrate while temperature-controlling each of the heaters.

In another aspect of this embodiment, a film-forming method comprising: providing a second reflector between the inner wall of the film-forming chamber and the liner, so that the second reflector surrounds the second heater, thereby heating the substrate.

In another aspect of this embodiment, a film-forming method comprising: providing a second insulator between the inner wall of the film-forming chamber and the second reflector thereby heating the substrate.

### BRIEF DESCRIPTION OF THE DRAWINGS

FIG. 1 is a schematic cross section of a film-forming apparatus according to the first embodiment.

FIG. 2 shows a state of the insulation moving in a downward direction in a film-forming apparatus according to the first embodiment.

FIG. 3 shows an example of the insulator.

FIG. 4 shows another example of the insulator.

FIG. 5 is a schematic cross section of a film-forming apparatus according to the second embodiment.

### DETAILED DESCRIPTION OF EMBODIMENT

### Embodiment 1

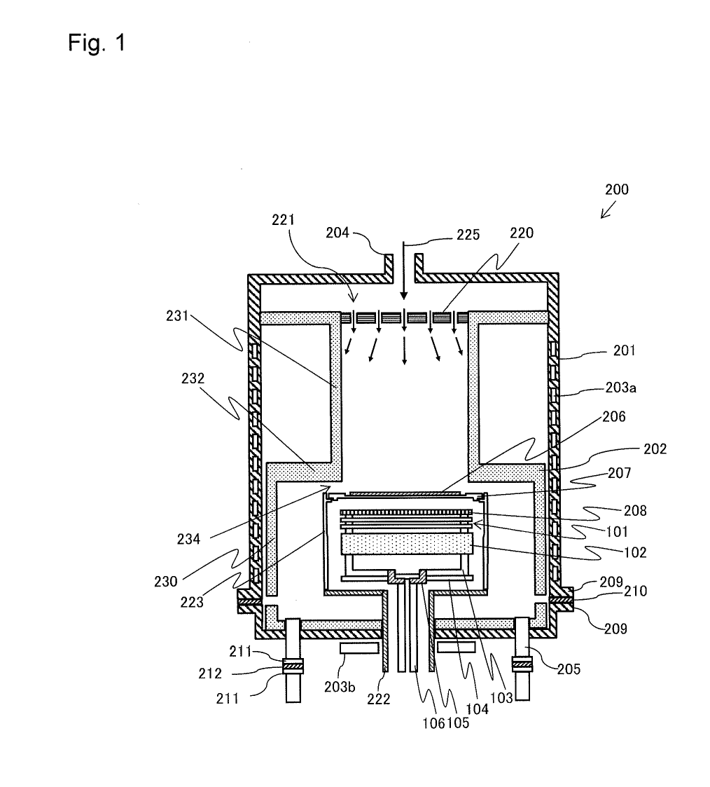

FIG. 1 is a schematic cross section of a film-forming apparatus according to the present embodiment.

As illustrated in FIG. 1, the film-forming apparatus 200 includes the following components: a chamber 201 as a film forming chamber, a hollow column-shaped liner 202 for covering to protect the inner wall of the chamber 201, coolant passageways 203a and 203b through which coolant water flows to cool the chamber 201, a gas inlet 204 from which a deposition gas 225 is introduced, gas outlets 205 from which to discharge the deposition gas 225 after use, a semiconductor substrate 206 (e.g., a wafer) on which vapor-phase epitaxy is performed, a susceptor 207 for supporting the semiconductor substrate 206, a heater 208 fixed to a support (not illustrated) for heating the semiconductor substrate 206, flanges 209 for connecting the upper and lower sections of the chamber 201, a packing material 210 for sealing the flanges 209, flanges 211 used for connection of the gas outlets 205 to pipes and packing materials 212 for sealing the flanges 211.

The liner 202 is made of transparent quartz. A shower plate 220 is fitted into the upper opening of the top portion 231 of the liner 202. The shower plate 220 functions as a flow-straightening vane for uniformly supplying the deposition gas 225 to the surface of the semiconductor substrate 206.

A rotary shaft 222 extends upwardly into the chamber 201 from the bottom of the chamber 201. A rotary drum 223 is placed on the upper end of the rotary shaft 222, and a susceptor 207 is fitted onto the top surface of the rotary drum 223. Therefore, the susceptor 207 can be rotated via the rotary drum 223, and consequently the semiconductor substrate 206 can be rotated via the susceptor 207. According to this method, the film-forming rate can be increased when deposition gas is continuously supplied to the surface of a uniformly heated semiconductor substrate 206.

A top portion of the chamber 201 is provided with a gas inlet 204 for supplying the deposition gas 225. The gas supplied from the gas inlet 204 is introduced through the shower plate 220 into the inside of the liner 202. Through-holes 221 provided in the shower plate 220 correspond to the position of the semiconductor substrate 206, and therefore the deposition gas 225 provided from the gas inlet 204 can be provided accurately onto the semiconductor substrate 206 placed on the susceptor 207.

In the cylindrical-shaped liner 202, the top portion 231 supporting the shower plate 220 has an inner diameter smaller than that of the body portion 230 in which the susceptor 207 is placed. That is, the liner 202 is constructed such that the inner diameter of the top portion 231 for supporting the shower plate 220, is smaller than that of the body portion 230 in which the semiconductor substrate 206 is placed. The top portion 231 of the liner 202 has a narrower cross-sectional area than that of the body portion 230.

According to the above-mentioned apparatus, the deposition gas 225 supplied through the through-holes 221 of the shower plate 220 can be efficiently focused on the surface of the semiconductor substrate 206 without wasting the deposition gas 225.

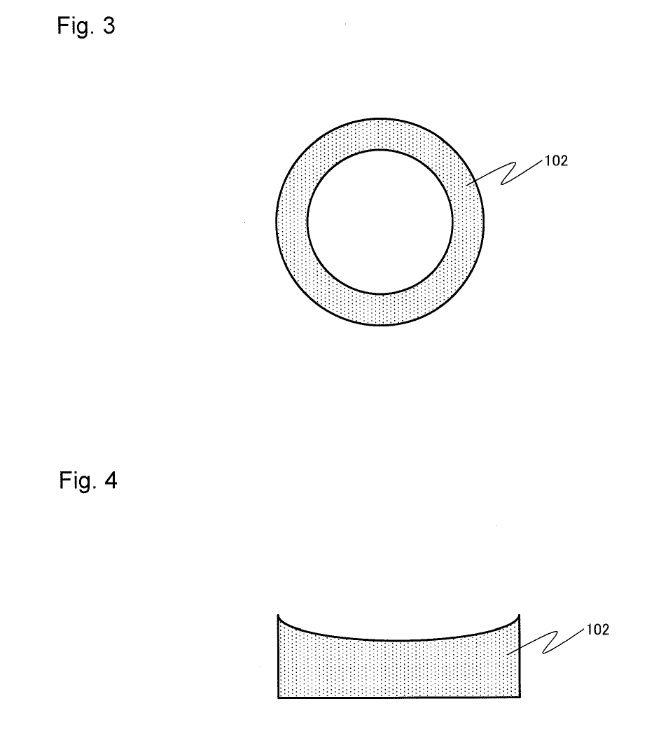

When the deposition gas 225 is supplied from the gas inlet 204 into the chamber 201, the deposition gas 225 flows downward inside the top portion 231 and moves toward the top surface of the substrate 206 in an efficient manner, see FIG. 3 to note that the space between the periphery of the substrate 206 and the liner 202 is narrow so that the deposition gas 225 can flow over the semiconductor substrate 206 in the form of a laminar flow. The liner 202 further includes a stepped section 232 that connects the top portion 231 and the barrel section 230, and the space between the corner 234 of this stepped section 232 and the periphery of the semiconductor substrate 206 is narrow.

A heater 208 (corresponding to a first heater in the present invention) is provided in the rotary drum 223. A resistive heater made from a material such as SiC is used as the heater 208. Specifically, it is an SiC heater including sintered SiC, as a heat source. The benefits of sintered SiC include: few impurities in the grain boundary, hyperfine and uniform structure, and a high electrically conductivity. Carbon (C) is more preferable than SiC from the perspective of heat resistance, however, considering the effect of impurities on an epitaxial film, SiC is preferable.

The heater 208 has a heating element that is constructed from sintered SiC and heated by an electric current. The sintered SiC is coated with SiC, that is, a plurality of SiC films that are formed on the sintered SiC sequentially while changing the forming-temperature.

The sintered SiC is made by sintering a powder of SiC, for example, a mixture of a plurality of powder of SiC having a different mean particle size are sintered. The mixture ratio and mean particle size are determined based on the electrical resistivity. The mixture is formed to a desired shape, and then it is sintered at a predetermined temperature, the method of sintering and specific atmosphere during sintering are not limited to this.

The shape of the heater 208 is not limited to the structure shown in FIG. 1. The semiconductor substrate 206 can be heated by two heaters, for example, an in-heater and out-heater. In this case, the out heater mainly heats the periphery of the susceptor 207, the in-heater positioned at the bottom of the out-heater may be used to heat the inside of the periphery of the susceptor 207. In this way, the semiconductor substrate 206 can be more uniformly heated, thereby improving the uniformity of temperature distribution in the semiconductor substrate 206.

The heater 208 is supported by an electrically conductive arm-like busbar (a first supporting unit) 103. The busbar 103 is made of, for example, a SiC-coated carbon material, and is supported by the heater base (a second supporting unit) 104. The heater base is made of quartz. The connecting portions 105 are formed of a metal such as molybdenum, the busbar 103 and the connecting portion (electrode) are connected by the connecting portions 105. Electricity can be conducted from rod electrodes 106 (these can also be referred to as ‘electrodes’) through the busbars 103 to the heater 208. Specifically, electricity is conducted from the rod electrodes to a heat source of the heater 208, and then the temperature of the heat source will increase.

The surface temperature of the semiconductor substrate 206 heated by the heater 208 can vary, therefore the surface temperature is measured by a radiation thermometer while heating is performed. The thermometer can be provided at the upper section outside of the chamber 201 (as one example). It is preferred that the shower plate 220 be formed of quartz, because the use of quartz prevents the shower plate 220 affecting the temperature measurement of the radiation thermometer. After temperature measurement the data is sent to a control device (not illustrated) and then fed back to an output control device of the heater 208. Therefore, it is possible to heat the semiconductor substrate 206 to a predetermined temperature.

Inside the rotating cylinder 223, a reflector 101 is provided under the heater 208 (which is a first reflector of the present invention). By providing the reflector 101, heat from the heater 208 is reflected and thus the heating efficiency of the semiconductor substrate 206 placed on the susceptor 207 can be improved. The reflector 101 is constructed from a material with a high heat resistance and high thermal conductivity such as carbon and it is preferable that the reflector 101 is placed in the vicinity of the heater 208.

The reflector 101 can consist of a single sheet or preferably consists of a plurality of sheets placed at predetermined intervals, in order to achieve the above effect. In the example of FIG. 1, the reflector 101 consists of two sheets placed at predetermined intervals, also the reflector 101 can consist of three sheets or more placed at predetermined intervals. In the present embodiment, the reflector 101 preferably consists of five sheets placed at predetermined intervals.

In the film-forming apparatus 200, when the heater 208 is operating, the surrounding components, that is, the busbar 103, the heater base 104, the connecting portions 105 and electrodes 106 are heated by radiant heat from the heater 208. Of these, the heater base 104 is composed of quartz, and the connecting portions 105 and the rod electrode are constituted of a metal, such as molybdenum. The heat resistance of these is lower than that of the SiC components of the heater 208. Therefore, there is a concern that these parts will deform as a result of heat radiation from the heater 208.

For films grown on Si, the temperature of the wafer is heated to approximately 1200° C. In the epitaxial growth of SiC films, the temperature of the wafer is heated to between 1650° C.-1750° C. However, the softening point of quartz is about 1100° C., as a result when performing epitaxial growth at high temperatures such as these, the heater base 104 may deteriorate.

Deterioration of the surrounding material can be reduced by providing a reflector 101. That is, the reflector 101 can reflect heat from the heater 208 to the semiconductor substrate 206 thus preventing deterioration of the surrounding material. However, if the film-forming process requires heating at high temperatures, such as for a Si film or a SiC film, the reflector 101 is not sufficient to prevent degradation of the surrounding material.

Therefore, in this embodiment, the reflector 101 is used in combination with an insulator 102 (which is the first insulator of the present invention). Specifically, the reflector 101 is disposed below the heater 208, further the insulator 102 (the first insulator in the present invention) is placed below the reflector 101. The insulator 102 can be made from carbon fiber, as one example. The insulator 102 absorbs the radiant heat from the heater 208, therefore it is possible to suppress an excessive rise in temperature around the heater 208. Subsequently, it is possible to prevent thermal degradation of components in close proximity to the heater 208. For example, when the temperature of the semiconductor substrate 206 is 1650° C., according to the configuration of this embodiment, the temperature of the heater base 104 may be about 1000° C. This is lower than the softening point temperature of the quartz, preventing deformation of the heater base 104.

The insulator 102 has the characteristic that the heat stored in it is not likely to be dissipated, therefore the insulator 102 is placed as far as possible from the semiconductor substrate 206. In the present embodiment, the insulator 102 is placed below the reflector 101 and as far as possible from the reflector 101. This makes it possible to minimize the effect of temperature control on the semiconductor substrate 206 and to prevent degradation of the surrounding material of the heater 208.

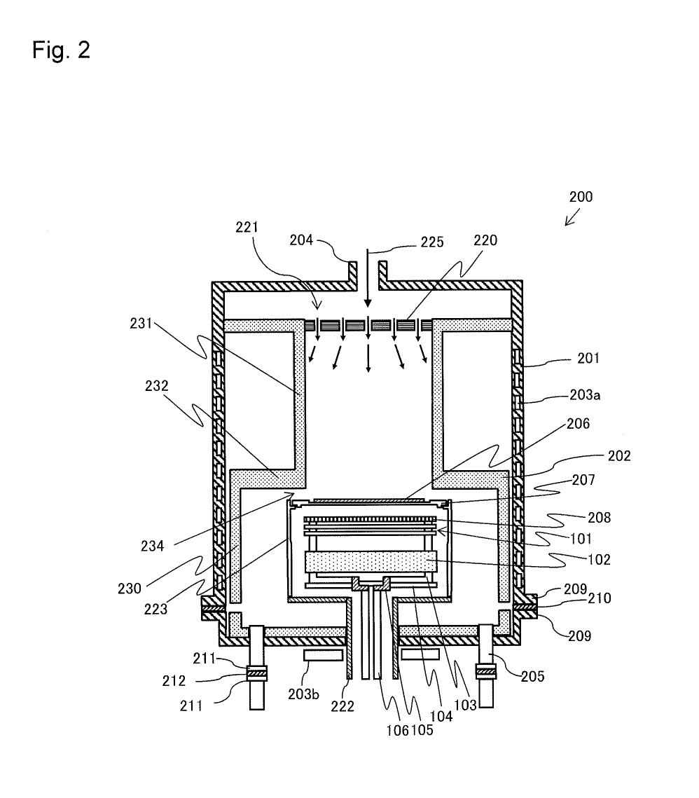

The insulator 102 has a structure moveable in the vertical direction. For example, when the temperature of the semiconductor substrate 206 will be increased to form an epitaxial film, the position of the insulator 102 should be moved upward, that is, close to the semiconductor substrate 206. After the epitaxial reaction is finished, when the temperature of the semiconductor 206 will be decreased to take out the semiconductor substrate 206 from the chamber 201, as shown FIG. 2, the position of the insulator 102 should lower away from the semiconductor substrate 206.

In the present embodiment, the distance between the heater 208 and the reflector 101 can be 5 mm. When the reflector 101 consists of five sheets, for example, the thickness of a sheet can be 2 mm, and the distance between these sheets can be 3.5 mm. Also, the distance between the reflector 101 and the insulator 102 can be 3.5 mm, and the thickness of the insulator 102 can be 25 mm. Further the distance to the lower part of the insulator 102 from the busbar 103 can be about 80 mm.

A plurality of insulators 102 can be located in a vertical direction in order to carefully adjust the temperature of the semiconductor substrate 206 by the insulator 102. For example, the insulator 102 can consist of two or three sheets placed at predetermined intervals.

The shape of the insulator 102 may be donut-shaped as shown in FIG. 3. Further, as shown in FIG. 4, the insulator 102 is disc-shaped, in this example the thickness of the center may be greater than the thickness of the shape at the periphery. Using the insulator 102 shown in FIG. 3 or FIG. 4 can reduce the impact on the semiconductor substrate 206 by preventing the thermal degradation of components in close proximity of the heater 208.

Next, the description of a film-forming method according to the first embodiment will be described.

In the film-forming apparatus 200, the semiconductor substrate 206 is supported by the susceptor 207 in the chamber 201. Then, while rotating the susceptor 207, the semiconductor substrate 206 placed on the susceptor 207 is heated to over 1000° C. using the heater 208. In this situation, a deposition gas 225 enters through a gas inlet 204 into the chamber 201 via the through-holes 221 of the shower plate 220.

Then, an epitaxial film is formed on the surface of the semiconductor substrate 206 by hydrogen reduction of a deposition gas on the surface of the semiconductor substrate 206. At that time, deposition gas other than that used for vapor phase growth reaction is turned into denatured production gas and is discharged together with the deposition gas 225 through the discharge portion 205 in the lower part of the chamber 201.

Next, a film-forming method for epitaxial Si film deposition will be described.

First, the semiconductor substrate 206 is moved into the chamber 201 and placed on the susceptor 207. The material of the semiconductor substrate 206 may be, for example, SiC, Si, SiO₂ (quartz) or another insulator. A highly resistive semi-insulating substrate such as GaAs (gallium arsenide) can also be used.

Next, the Si film is formed on a semiconductor substrate 206.

For example, an Si wafer can be used as the semiconductor substrate 206, the Si wafer is placed on the susceptor 207. If the insulator 102 is moveable in vertical direction, the position of the insulator 102 should be moved upward, that is, close to the semiconductor substrate 206.

Then, the susceptor 207 on which the semiconductor substrate 206 is attached is rotated at approximately 50 rpm, while hydrogen gas flows at atmospheric pressure or under an appropriate reduced vacuum pressure.

Next, the heater 208 is activated to heat the Si wafer up to, for example, 1100° C.-1200° C. The heat of the heater 208 will be stored in the insulator 102 and therefore the Si wafer can be heated efficiently.

After the radiation thermometer (not illustrated) registers 1150° C., confirming that the temperature of the Si wafer has reached that value, the rotational speed of the Si wafer is gradually increased. Thereafter, the deposition gas is supplied from the gas inlet 204 via the shower plate 220 into the chamber 201.

Trichlorosilane is used as the deposition gas. After being mixed with a hydrogen gas, which acts as a carrier gas, the deposition gas is supplied through the gas inlet 204 into the chamber 201. The deposition gas introduced into the chamber 201 flows downward toward the Si wafer. The fresh deposition gas is continuously supplied from the gas inlet 204 to the Si wafer 101 through the shower plate 220 while the temperature of the Si wafer is kept at approximately 1150° C. and the susceptor 207 is rotated at a speed of approximately 900 rpm or more.

As described above, a Si epitaxial film having a uniform thickness can be grown on the Si wafer.

As noted above, in the Si epitaxial growth process, when using a heater 208 for heating the semiconductor substrate 206, radiant heat from the heater 208 causes the temperature of other components to rise, as well as the semiconductor substrate 206. These components are located in the vicinity of the heater 208, for example, busbar 103, heater base 104, connecting portion 105 and electrodes 106. The radiant heat from the heater 208 rises above the softening point temperature of the surrounding components, and deformation can occur in the peripheral parts.

Therefore, the reflector 101 is located below the heater 208, furthermore, insulator 102 is located below the reflector 101. The reflector 101 reflects the heat of the heater 208 towards the semiconductor substrate 206. In addition, the insulator 102 absorbs the heat from the heater 208. Thus, according to this configuration, suppressing the excessive rise in temperature around the heater at 208 can prevent thermal degradation of components in close proximity of the heater 208.

After the formation of a Si film having a predetermined thickness on the semiconductor substrate 206, supply of the deposition gas 225 is stopped. After it is confirmed that the semiconductor substrate 206 has been cooled to a predetermined temperature, the semiconductor substrate 206 is taken out of the chamber 201. If the insulator 102 has a structure moveable in a vertical direction, the insulator 102 moves down so that the insulator 102 is away from the semiconductor substrate 206, thus making it possible to cool the semiconductor substrate 206 faster.

Another example of the SiC epitaxial film deposition method will now be described.

First, the semiconductor substrate 206 is placed on the susceptor 207, and then the semiconductor substrate 206 is heated while rotating the semiconductor substrate 206 via the susceptor 207. By supplying the reactant gas to the surface of the semiconductor substrate 206 in this state, an SiC epitaxial film is formed on the surface of the semiconductor substrate 206.

As an example of the material used for the semiconductor substrate 206, an insulating substrate such as SiC, Si, SiO₂ (quartz), or a semi-insulating substrate such as a high-resistance GaAs (gallium arsenide) can be used.

First, the semiconductor substrate 206 is transported into the chamber 201. Next, the semiconductor substrate 206 placed on the susceptor 207 is rotated at about 50 rpm by rotation of the susceptor 207.

The heater 208 is operated by supplying electric current thereto, to heat the semiconductor substrate 206 by heat emitted from the heater 208. The semiconductor substrate 206 is gradually heated until the temperature of the semiconductor substrate 206 reaches a predetermined value in the range of 1500-1700° C. at which time a SiC film is formed, for example, 1650° C. At this time, an excessive increase in the temperature of the chamber 201 can be prevented by allowing cooling water to flow through the flow paths 203a and 203b provided in the wall of the chamber 201.

After reaching 1650° C., the temperature of the semiconductor substrate 206 is carefully maintained at a temperature of around 1650° C. by the heater 208. At this time, the temperature of the semiconductor substrate 206 is measured by a radiation thermometer (not shown).

Then, after it is confirmed that the temperature of the semiconductor substrate 206 measured by the radiation thermometer has reached a predetermined temperature, the number of revolutions of the semiconductor substrate 206 is gradually increased. For example, the number of revolutions of the semiconductor substrate 206 can be increased to 900 rpm.

Further, the deposition gas 225 is supplied from the gas inlet 204 so as to flow downward through the shower plate 220 onto the semiconductor substrate 206. At this time, the flow of the deposition gas 225 is straightened by allowing the deposition gas 225 to pass through the shower plate 220 serving as a straightening vane so that the deposition gas 225 flows substantially vertical downward toward the semiconductor substrate 206 placed under the shower plate 220. That is, the deposition gas 225 forms a so-called vertical flow.

As a deposition gas 225, SiH₄ (monosilane) and C₃H₈ (propane) can be used, and mixed with hydrogen gas as a carrier gas supplied from a gas inlet 204 into the chamber 201. In addition, SiH₆ (disilane), SiH₃Cl (Monochlorosilanes), SiH₂Cl₂ (dichlorosilane), SiHCl₃ (trichlorosilane), SiCl₄ (tetrachlorosilane) etc. may be used instead of SiH₄.

It is to be noted that in addition, at the top of the chamber 201, the gas inlet 204 supplies a deposition gas, and another gas supply inlet portion can be used for supplying hydrogen gas as a carrier gas, into the chamber 201. In this case, deposition gas including carbon, for example acetylene, is supplied from the gas inlet 204, and carrier gas is supplied from the carrier gas supply portion, and both carrier gas and deposition gas are mixed in the chamber 201, and supplied to the surface of the semiconductor substrate 206.

When the deposition gas 225 reaches the surface of the heated semiconductor substrate 206, a thermal decomposition reaction or a hydrogen reduction reaction occurs so that a SiC epitaxial film is formed on the surface of the semiconductor substrate 6. Deposition gas other than that used for a vapor-phase growth reaction is turned into a denatured production gas and discharged through the discharge portion 205 provided in the lower part of the chamber 201.

In order to form a SiC epitaxial film, the temperature of the semiconductor substrate 206 needs to be increased to 1500° C. or higher. For this reason, the susceptor 207 needs to be made of highly heat-resistant material. More specifically, one obtained by coating the surface of isotropic graphite with SiC by CVD (Chemical Vapor Deposition) is used (as one example). The shape of the susceptor 207 is not particularly limited as long as the semiconductor substrate 206 can be placed on the susceptor 207, and may be appropriately selected. Examples can include a ring shape and a solid disk shape.

As noted above, in the SiC epitaxial growth process, the semiconductor substrate 206 needs to be at a very high temperature. However, when heated by only the heater 208, radiant heat from the heater 208 will cause the semiconductor substrate 206 as well as other components to rise in temperature. These components are located in the vicinity of the heater 208, for example the busbar 103, heater base 104, the connecting portion 105 and electrodes 106. The radiant heat from the heater 208 causes these surrounding components to rise above their softening point temperature and thus deformation of these parts can occur.

The reflector 101 is placed below the heater 208, insulator 102 is placed below the reflector 101. Then, the heat from the heater 208 is reflected towards the semiconductor substrate 206 by the reflector 101. In addition, heat is absorbed from the heater 208 by the insulator 102. Thus, according to this configuration, suppression of the excessive rise in temperature around the heater 208 can prevent the thermal degradation of components in close proximity of the heater 208.

After forming an SiC film of a predetermined thickness on the semiconductor substrate 206 the supply of deposition gas 225 is stopped. Once it is confirmed that the semiconductor substrate 206 is cooled to a predetermined temperature, the semiconductor substrate 206 is moved out of the chamber 201.

According to the film-forming method of the present embodiment, as described above, the combination of the reflector and insulator are provided below the heater thereby preventing the deterioration of components by radiant heat from the heater 208. The film-forming apparatus and film-forming method of the present embodiment can be applied to the film-forming of epitaxial Si film or SiC epitaxial film and is especially suitable for film formation at high temperatures, such as SiC epitaxial films.

In accordance with the first embodiment of this invention, it is possible to limit damage of the surrounding components as a result of heat irradiated from the heater.

### Embodiment 2

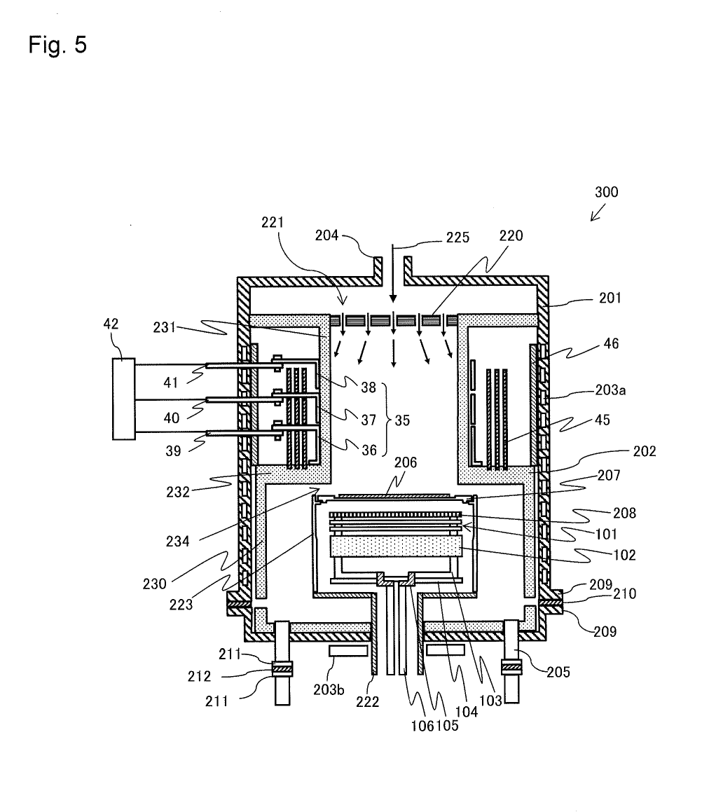

FIG. 5 is a schematic cross-sectional view of a film-forming apparatus in this embodiment. In FIG. 5, the same reference numerals as used in FIG. 1 refer to the same components.

In the film-forming apparatus 300, the upper heater 35 (as a second heater) is provided at the outer circumference of the perimeter of the liner 202, more specifically, the outer top portion 231 of the liner 202. In other words, in the film-forming apparatus 300, the heater 208 is positioned on the lower surface of the semiconductor substrate 206, for heating the underside of the semiconductor substrate 206, and an upper heater 35 is located above the heater 208 and around the liner 202, for heating the upper surface of the semiconductor substrate 206. According to this configuration, the upper heater 35 is located above the heater 208 (as a first heater).

The upper heater 35 can be constituted by a plurality of heaters, and each heater can be controlled independently.

In FIG. 5, the upper heater 35 consists of three heaters arranged in the vertical direction (first heater 36, second heater 37, and third heater 38). These heaters are resistance heaters and are made of carbon (C).

The heaters are arranged sequentially from the side of the liner 202 closest to the body portion 230 in the direction of the upper opening wherein the shower plate 220 is disposed. These heaters are supported by connecting portions, for example, the first heater connecting portion 39 supports the first heater 36 by means such as screwing, the second connecting portion 40 connects the second heater 37 by means such as screwing, and the third heater connecting portion 41 supports the third heater 38 by means such as screwing. In addition, the first heater connecting portion 39, second heater connecting portion 40, and third heater connecting portion 41 extend through the sidewall of the chamber 201, these heater connecting portions are connected to the heater current supply unit (not shown) via the control unit 42. In this structure, the heater current supply is performed independently. Specifically, the heater current is supplied through the first heater connecting portion 39 to the first heater 36, the heater current for the second heater is supplied through the second heater connecting portion 40 to the second heater 37, and the heater current for the third heater is supplied through the third heater connecting portion 41 to the third heater 38. The control unit 42 can control the current for a first heater 36, second heater 37, and third heater 38, thereby adjusting the temperature of each heater.

As shown in FIG. 5, the first heater 36 is located at the lowest position of the heaters used to make up the upper heater 35, and has a shape similar to the liner 202. That is, the first heater 35 has a bend on the lower side, to address the shape of the boundary between the top portion 231 and the body portion 230. This makes it possible to efficiently heat the semiconductor substrate 206.

In the film-forming apparatus 300, the number of heaters used to make up the upper heater 35 is not limited to three and may be, for example, two or four or more. In addition, in the upper heater 35, instead of a combination of heaters, the upper heater 35 can also consist of a single heater.

In FIG. 5, the film-forming apparatus 300 has a reflector 45 (as a second reflector) between the sidewall of the chamber 201 and the top portion 231 of the liner 202. The reflector 45 is placed around the first heater 36, the second heater 37 and the third heater 38 that form the upper heater 35. As the heat from the upper heater 35 is reflected by the reflector 45, heat efficiency to the semiconductor substrate 206 can be increased. Also the reflector 45 can prevent heat from the upper heater 35 reaching the sidewall of the chamber 201, and the temperature of the chamber 201 increasing excessively.

The reflector 45 is made of carbon having a highly heat-resistant and a highly thermal conductivity. In the example of FIG. 5, the reflector 45 is placed at the top of the body portion 230, that is, in the boundary between the body port ion 230 and the top portion 231 of the liner 202. In FIG. 5, the reflector 45 has a structure consisting of three layers to reflect efficiently the heat from the upper heater 35 to the semiconductor substrate 206. The reflector 45 can have a structure consisting of one layer, two layers, or four or more layers, in consideration of the performance of reflecting heat or preventing heat.

In the present embodiment, the insulator 46 (as a second insulator) is placed in the upper heater 35 position, covering the inner wall of the chamber 201. The excessive heat from the upper heater 35 is prevented by the insulator 46, therefore the insulator 46 can prevent the temperature of the sidewall of the chamber 201 increasing excessively by the upper heater 35. The sidewall is made from stainless steel, as one possible example.

In the film forming apparatus 300 of the present embodiment, as well as the film forming apparatus 200 in the first embodiment, a reflector 101 (as a first reflector) is placed below the heater 208 (as a first heater), further an insulator 102 (as a first insulator) is placed below the reflector 101. The heat from the heater 208 is reflected toward the semiconductor substrate 206 by the reflector 101 and the heat from the heater 208 is absorbed by the insulator 102. Therefore, this makes it possible to reduce the temperature around the heater 208 from increasing excessively and prevent the deterioration of materials or components surrounding the heater by radiant heat.

As described above, according to this embodiment, placing the insulator 102 under the heater 208 in combination with the reflector 101 can prevent the deterioration of the surrounding components by radiant heat from the heater 208. In addition, by providing the upper heater 35 for heating from above the semiconductor substrate 206, coupled with the heater 208 the semiconductor substrate 206 can be preferably heated. Further the reflector 45 and the insulator 46 can prevent the heat from the upper heater 35 reaching the sidewall of the chamber 201, and the temperature of the chamber 201 increasing excessively.

Incidentally, in this embodiment it is possible that the insulator 46 and the reflector 45 may not be provided around the upper heater 35, or only the reflector 45 is provided around the upper heater 35.

Next, the film-forming method of Embodiment 2 will be described.

The film-forming apparatus 300 according to this embodiment is similar to the first embodiment in that the apparatus can be applied to the film-forming of Si and SiC epitaxial film. In particular, such a film-forming apparatus used for SiC epitaxial films is suitable when the film is formed at very high temperatures while maintaining a uniform temperature of the substrate.

A SiC epitaxial film can be formed using the film-forming apparatus 300 in the following method.

First, SiC wafer as the semiconductor substrate 206 is moved into the interior of the chamber 201. Next, the semiconductor substrate 206 is placed on the susceptor 207. In this case, the vertically movable insulator 102 is to be located close to the semiconductor substrate 206.

Then, while rotating the semiconductor substrate 206 at a speed of approximately 50 rpm hydrogen gas flows at atmospheric pressure or under vacuum appropriate reduced pressure.

Next, the semiconductor substrate 206 is heated by the heater 208 and the upper heater 35. At this time, heating temperature can be controlled independently via adjustments to the multiple heaters that make up the upper heater 35. Power to the heater 208 can be supplied from the electrodes 106 via the connecting portion 105 and the busbar 103. As a result, the temperature of the heating source increases in the heater 208. In addition, the current is independently supplied through the first heater connecting portion 39, the second heater connecting portion 40 and the third heater connecting portion 41 to the first heater 36, second heater 37, and third heater 38 used to make up the upper heater 35 and then the temperature of the heating sources increase in these heaters.

In the present embodiment, reflector 101 is located below the heater 208, further, the insulator 102 is provided below the reflector 101 thus allowing heat from the heater 208 to be reflected to the semiconductor substrate 206. In addition, the insulator 102 can absorb the radiant heat from the heater 208. Therefore, suppressing the excessive rise in temperature around the heater 208 can prevent the thermal degradation of materials in close proximity to the heater 208.

In the film forming apparatus 300, the upper heater 35 is placed around the top portion 231 of the liner 202. Therefore the upper heater 35 and the heater 208 combine to make the semiconductor substrate 206 increase to a high temperature efficiently. Further the upper heater 35 is formed of a plurality of heaters, and these heaters can be controlled independently. This makes it possible to adjust carefully the temperature of the semiconductor substrate 206, and to make uniform the temperature distribution to the semiconductor substrate 206.

In addition, the film-forming apparatus 300 has a reflector 45 (as a second reflector) between the inner wall of the chamber 201 and the top portion 231 of the liner 202. Further the insulator 46 is placed in close proximity to the position of the upper heater 35, covering the inner wall of the chamber 201. As the heat from the upper heater 35 is reflected by the reflector 45 heat efficiency to the semiconductor substrate 206 can be increased. Also the reflector 45 can prevent the heat from the upper heater 35 reaching the sidewall of the chamber 201, and the temperature of the chamber 201 increasing excessively. The heat from the upper heater 35 is efficiently prevented by the insulator 46, therefore the insulator 46 can prevent the temperature of the sidewall of the chamber 201 increasing excessively.

The semiconductor substrate 206 is heated via the heater 208 and the upper heater 35 until reaching a predetermined temperature, in the range of 1500° C.-1700° C. (for example 1650° C.). At this time, an excessive increase in the temperature of the chamber 201 can be prevented by allowing cooling water to flow through the flow paths 203a and 203b provided in the wall of the chamber 201.

After reaching 1650° C., the heater 208 can perform precise temperature control to maintain the temperature in this vicinity. The upper heater 35 acts to help regulate the temperature of the heater 208. For example, if the temperature of the semiconductor substrate 206 is to be maintained at 1650° C., the first heater 36, the second heater 37, and the third heater 38 used to make up the upper heater 35 are adjusted such that the temperature will be in a range of 1700° C.-1800° C., therefore the upper heater 35 can be less than 1800° C. In other words, with the combination of the heater 208 and the upper heater 35, it is possible to prevent the heater 208 from rising to excessive temperatures. Therefore, by the use of the upper heater 35 assisting the heater 208 excessive temperature rises around the heater 208 can be prevented and therefore avoid deterioration or damage to components surrounding the heater 208.

After the radiation thermometer (not shown) confirms that the temperature of the semiconductor substrate 206 has reached a predetermined temperature, the rotational speed of the semiconductor substrate 206 will be increased gradually to a rotational speed of about 900 rpm. Then, a deposition gas 225 is supplied into the chamber 201 via the gas inlet 204. As a deposition gas 225, SiH₄ (monosilane) and C₃H₈ (propane) can be used, and mixed with hydrogen gas as a carrier gas supplied from a gas inlet 204 into the chamber 201. In addition, SiH₆ (disilane), SiH₃Cl (Monochlorosilanes), SiH₂Cl₂ (dichlorosilane), SiHCl₃ (trichlorosilane), SiCl₄ (tetrachlorosilane) etc. maybe used instead of SiH₄.

The deposition gas 225 introduced into the chamber 201, passes through the shower plate 220 that is fitted into the top portion 231 of the liner 202. The shower plate 220 having lots of through-holes 221, functions as a flow straightening vane. The deposition gas 225 passed through the shower plate 220, flows down becoming a uniform flow, toward the semiconductor substrate 206, a SiC film is then formed on the semiconductor substrate 206.

After an epitaxial film of a particular thickness is deposited on the semiconductor substrate 206, the supply of the deposition gas 225 is stopped. The supply of the carrier gas can also be stopped at the same time, alternatively, after only the supply of the deposition gas is stopped, the supply of the carrier gas can also be stopped after the temperature of the semiconductor substrate 206 as measured by the radiation thermometer becomes lower than a predetermined temperature.

After being cooled to a predetermined temperature, the semiconductor substrate 206 is moved out of the chamber 201. If the insulator 102 is vertically movable, the insulator 102 should move down to be away from the semiconductor substrate 206 thus accelerating cooling of the semiconductor substrate 206.

According to the film-forming method of this embodiment, the combination of a first reflector and a first insulator are provided below the first heater to heat the substrate, therefore performing efficient epitaxial growth on the substrate at high temperature while avoiding damage to components surrounding the first heater by the heat from the first heater. Since the substrate is heated by the second heater located above the substrate, it is possible to efficiently heat the substrate with the combination of first and second heaters. The use of the second heater prevents excessive temperature rise of the first heater, therefore it is possible to further reduce the impact of heat from the heater to the components surrounding the first heater. In addition, by placing a second reflector around a second heater, the second reflector can prevent heat from the second heater reaching the sidewall of the chamber, and the temperature of the chamber increasing excessively. Further, by placing a second insulation around the second reflector, the heat from the second heater is more efficiently prevented by the second insulator, therefore the insulator 46 can prevent the temperature of the sidewall of the chamber increasing excessively.

In accordance with the second embodiment of this invention, it is possible to limit damage of the surrounding components as a result of heat irradiated from heater.

Features and advantages of the present invention can be summarized as follows.

According to the film-forming apparatus of the present invention, it is possible to suppress the deterioration of the surrounding material by radiant heat from the heaters.

According to the film-forming method of the present invention, while preventing the deterioration of the surrounding material by radiant heat, film-forming can be performed.

The present invention is not limited to the embodiments described above and can be implemented in various modifications without departing from the spirit of the invention.

For example, the above embodiments 1 and 2 have been described as an example of a film-forming process while rotating the substrate in a film-forming chamber, the present invention is not limited to this. The film-forming apparatus of the present invention may be deposited on the substrate while stationary and not rotating.

In addition to the above embodiments, an epitaxial growth system cited as an example of a film-forming apparatus in the present invention is not limited to this. Deposition gas supplied into the film-forming chamber for forming a film on its surface while heating the wafer, can also be applied to a CVD (Chemical Vapor Deposition) film-forming apparatus.

1. A film-forming apparatus comprising:
a film-forming chamber;
a first heater located in the film-forming chamber;
a first reflector located below the first heater; and
a first insulator located below the first reflector.

2. The film-forming apparatus according to claim 1, wherein the first insulator is made of carbon fiber.

3. The film-forming apparatus according to claim 1, comprising:
a cylindrically-shaped liner covering an inner wall of the film-forming chamber; and
a second heater located above the first heater, between the inner wall of the film-forming chamber and the liner.

4. The film-forming apparatus according to claim 3,
wherein the second heater is formed from a plurality of heaters provided in a vertical direction; and
wherein the apparatus is comprised of a control unit for independently controlling the heaters.

5. The film-forming apparatus according to claim 3, wherein a second reflector is provided between the inner wall of the film-forming chamber and the second heater.

6. The film-forming apparatus according to claim 5, wherein a second insulator is provided between the inner wall of the film-forming chamber and the second reflector.

7. The film-forming apparatus according to claim 6, wherein the second insulator is made of carbon fiber.

8. The film-forming apparatus according to claim 1, comprising:
a susceptor, provided in the film-forming chamber to place the substrate thereon;
a electrically-conductive first support unit for supporting the first heater;
a second support unit for supporting the first support unit;
a rotary drum for supporting the susceptor at an upper section thereof, and further housing the first heater, the first support unit and the second support unit;
a rotary shaft, located at a lower section of the film-forming chamber, for rotating the rotary drum;
an electrode, located inside the rotary shaft, for conducting electricity through the first support unit to the first heater;
an electrically-conductive connector penetrated by the upper section of the electrode, for fixing the electrode and for supporting the first support unit and the second support unit;
wherein the first reflector and the first insulator are provided inside the rotary drum and between the first heater and the second support unit.

9. The film-forming apparatus according to claim 8,
wherein the second support unit is made of quartz; and
both the electrode and the connector are made of metal.

10. The film-forming apparatus according to claim 8, wherein the first insulator is made of carbon fiber.

11. The film-forming apparatus according to claim 8,
further comprising: a cylindrically-shaped liner covering an inner wall of the film-forming chamber; and
a second heater located above the first heater between the inner wall of the film-forming chamber and the liner.

12. The film-forming apparatus according to claim 11, wherein the second heater is formed by a plurality of heaters provided in a vertical direction; and further comprising a control unit for independently controlling the heaters.

13. The film-forming apparatus according to claim 11, wherein a second reflector is provided between the inner wall of the film-forming chamber and the second heater.

14. The film-forming apparatus according to claim 13, wherein a second insulator is provided between the inner wall of the film-forming chamber and the second reflector.

15. The film-forming apparatus according to claim 14, wherein the second insulator is made of carbon fiber.

16. A method for depositing a film onto a surface of a substrate, the method comprising:
placing the substrate on a susceptor located on a rotary drum in a film-forming chamber;
heating the substrate while rotating the rotary drum by a rotary shaft provided at a lower section of the film-forming chamber; and
feeding a deposition gas into the film-forming chamber,
providing an electrode inside the rotary shaft;
providing a first heater, an electrically-conductive first support unit for supporting the first heater, a second support unit for supporting the first support unit, and an electrically-conductive connector for supporting the first support unit and the second support unit and for conducting electricity between the electrode and the first support unit, inside the rotary drum;
providing a first reflector below the first heater;
providing a first insulator below a first reflector and above the second support unit; and
conducting electricity from the electrode to the first heater to heat the substrate.

17. The film-forming method according to claim 16, comprising:
covering the inner wall of the chamber with a liner, and
wherein heating the substrate via the first heater and a second heater located above the substrate and between the inner wall of the film-forming chamber and the liner.

18. The film-forming method according to claim 17, comprising:
forming the second heater from a plurality of small heaters provided in a vertical direction; and
heating the substrate while temperature-controlling each of the heaters.

19. The film-forming method according to claim 17, comprising:
providing a second reflector between the inner wall of the film-forming chamber and the liner, the second reflector surrounding the second heater, thereby heating the substrate.

20. The film-forming method according to claim 19, comprising:
providing a second insulator between the inner wall of the film-forming chamber and the second reflector thereby heating the substrate.
